(19) United States
(12) Patent Application Publication
(10) Pub. No.: US 2004/0066872 A1
(43) Pub. Date: Apr. 8, 2004

(54) Method and apparatus for reducing clock jitter in a clock recovery circuit

(75) Inventor: Tse-Hsiang Hsu, Hsinchu City (TW)

Correspondence Address: BRINKS HOFER GILSON & LIONE, NBC Tower, Suite 3600, 455 N. Cityfront Plaza Drive, Chicago, IL, 60611-5599, US

(73) Assignee: MEDIA TEK INC.

(21) Appl. No.: 10/266,426

(22) Filed: Oct. 8, 2002

(51) Int. Cl. H03D 3/24

(52) U.S. Cl. 375/376; 375/371; 327/156

(57) ABSTRACT

In a method and apparatus for reducing clock jitter in a clock recovery circuit, a control signal having first and second potentials is generated from ascending and descending pulses of a phase detector that receives an input data signal and a clock signal. The current output of a charge controller is used to charge and discharge a capacitor when the control signal has the first potential such that the capacitor has a floating voltage. The capacitor is connected to a loop filter to enable the latter to generate a control voltage corresponding to the floating voltage when the control signal has the second potential. The control voltage is used to control an oscillator circuit for synchronizing the clock signal with the input data signal.

### BACKGROUND OF THE INVENTION

1. Field of the Invention

The invention relates to a clock recovery circuit, more particularly to a method and apparatus for reducing clock jitter in a clock recovery circuit.

2. Description of the Related Art

Phase locked loops are widely used in devices for frequency control, such as multipliers, demodulators, tracking generators, clock recovery circuits, etc. Currently, synchronized regeneration of data in optical disc mediums, such as CD-ROM, DVD, etc., is achieved with the use of clock recovery circuits. Referring to FIG. 1, a conventional clock recovery circuit 1 is shown to include a phase detector 11, a charge controller 12, a loop filter 13, a voltage-controlled oscillator (VCO) 14, and a frequency divider 15. The phase detector 11 receives an input data signal (DATA) (see FIG. 2A) and a clock signal (CLK) (see FIG. 2B) generated by the frequency divider 15 from a clock output of the oscillator 14. The phase detector 11 generates ascending pulses (UP) (see FIG. 2C) and descending pulses (DN) (see FIG. 2D) according to a phase difference (Δt) between the input data signal (DATA) and the clock signal (CLK). The ascending and descending pulses (UP, DN) are received by the charge controller 12, which generates a current output (I_{cp}) according to the ascending and descending pulses (UP, DN). The current output (I_{cp}) is integrated by the loop filter 13 to result in a control voltage (V_{ct}) (see FIG. 2E), which is used to control the oscillator 14 in order to synchronize the clock signal (CLK) with the input data signal (DATA). When the clock signal (CLK) is synchronized with the input data signal (DATA), the clock signal (CLK) can be used to sample the input data signal (DATA) for data regeneration.

In the conventional clock recovery circuit 1, when the phase of the clock signal (CLK) leads the input data signal (DATA), the phase detector 11 will output a narrower ascending pulse (UP) or a wider descending pulse (DN) to control the charge controller 12 to generate a negative current output (I_{cp}), which is subsequently integrated by the loop filter 13 to result in a smaller control voltage (V_{ct}) for reducing the frequency of the clock output of the oscillator 14. On the other hand, when the phase of the clock signal (CLK) lags the input data signal (DATA), the phase detector 11 will output a wider ascending pulse (UP) or a narrower descending pulse (DN) to control the charge controller 12 to generate a positive current output (I_{cp}), which is subsequently integrated by the loop filter 13 to result in a larger control voltage (V_{ct}) for increasing the frequency of the clock output of the oscillator 14.

It is noted that the phase detector 11 does not output the ascending pulse (UP) and the descending pulse (DN) simultaneously, i.e., the phase detector 11 first generates the ascending pulse (UP) before generating the descending pulse (DN). The control voltage (V_{ct}) is thus generated as a result of the integration of the ascending pulse (UP) and the descending pulse (DN) in their order of occurrence. As such, a side from the desired voltage difference (ΔV) corresponding to the phase difference (Δt), the control voltage (V_{ct}) further contains undesired ripples (Vᵣ). These undesired ripples (Vᵣ) are present even when the phase difference (Δt) is very small. Not only do the ripples (Vᵣ) drive the oscillator 14 to continuously change the phase of the clock signal (CLK), which results in phase jitter of the clock signal (CLK), they also rapidly increase and decrease the frequency of the clock signal (CLK). Therefore, when the clock signal (CLK) is used to sample the input data signal (DATA) in the conventional clock recovery circuit 1, shifting of the sampling points easily occurs to result in data sampling error. Moreover, the phase jitter will lead to the generation of ripples dependent on the frequency of transition edges of the input data signal (DATA), which is otherwise known as data dependent phase jitter.

### SUMMARY OF THE INVENTION

Therefore, the main object of the present invention is to provide a method and apparatus for reducing clock jitter in a clock recovery circuit.

According to one aspect of the present invention, there is provided a method for reducing clock jitter in a clock recovery circuit. The clock recovery circuit includes a phase detector for receiving an input data signal and a clock signal, a charge controller connected to the phase detector, a loop filter to be connected to the charge controller, and an oscillator circuit connected to the loop filter and the phase detector. The oscillator circuit includes a voltage-controlled oscillator, and provides the clock signal to the phase detector. The phase detector generates ascending and descending pulses according to phase difference between the input data signal and the clock signal. The charge controller generates a current output according to the ascending and descending pulses from the phase detector. The loop filter generates a control voltage for controlling the oscillator circuit to synchronize the clock signal with the input data signal. The method comprises the steps of:

generating a control signal from the ascending and descending pulses, the control signal having a first potential during a first time period beginning from a starting edge of one of the ascending pulses and ending at a finishing edge of one of the descending pulses that follows said one of the ascending pulses, and having a second potential during a second time period beginning from the finishing edge of said one of the descending pulses and ending at a starting edge of another one of the ascending pulses that follows said one of the descending pulses;

using the current output of the charge controller to charge and discharge a capacitor when the control signal has the first potential such that the capacitor has a floating voltage; and

connecting the capacitor to the loop filter to enable the loop filter to generate the control voltage corresponding to the floating voltage when the control signal has the second potential.

According to another aspect of the present invention, there is provided an apparatus for reducing clock jitter in a clock recovery circuit. The clock recovery circuit includes a phase detector for receiving an input data signal and a clock signal, a charge controller connected to the phase detector, a loop filter to be connected to the charge controller, and an oscillator circuit connected to the loop filter and the phase detector. The oscillator circuit includes a voltage-controlled oscillator, and provides the clock signal to the phase detector. The phase detector generates ascending and descending pulses according to phase difference between the input data signal and the clock signal. The charge controller generates a current output according to the ascending and descending pulses from the phase detector. The loop filter generates a control voltage for controlling the oscillator circuit to synchronize the clock signal with the input data signal. The apparatus comprises:

a control signal generator adapted to be connected to the phase detector and adapted to generate a control signal from the ascending and descending pulses, wherein the control signal has a first potential during a first time period beginning from a starting edge of one of the ascending pulses and ending at a finishing edge of one of the descending pulses that follows said one of the ascending pulses, and has a second potential during a second time period beginning from the finishing edge of said one of the descending pulses and ending at a starting edge of another one of the ascending pulses that follows said one of the descending pulses; and

a switch unit connected to the control signal generator and including a switch adapted to interconnect the charge controller and the loop filter, and a capacitor adapted to be connected to the charge controller and to the loop filter via the switch;

the switch being controlled by the control signal from the control signal generator such that when the control signal has the first potential, the charge controller and the capacitor are disconnected from the loop filter and the current output of the charge controller is used to charge and discharge the capacitor so as to result in a floating voltage of the capacitor, and such that when the control signal has the second potential, the charge controller and the capacitor are connected to the loop filter to enable the loop filter to generate the control voltage corresponding to the floating voltage.

According to yet another aspect of the present invention, there is provided a clock recovery circuit that comprises:

a phase detector for receiving an input data signal and a clock signal;

a charge controller connected to the phase detector;

a loop filter to be connected to the charge controller;

an oscillator circuit connected to the loop filter and the phase detector;

a control signal generator connected to the phase detector; and

a switch unit connected to the control signal generator.

The oscillator circuit includes a voltage-controlled oscillator, and provides the clock signal to the phase detector. The phase detector generates ascending and descending pulses according to phase difference between the input data signal and the clock signal. The charge controller generates a current output according to the ascending and descending pulses from the phase detector. The loop filter generates a control voltage for controlling the oscillator circuit to synchronize the clock signal with the input data signal.

The control signal generator generates a control signal from the ascending and descending pulses, wherein the control signal has a first potential during a first time period beginning from a starting edge of one of the ascending pulses and ending at a finishing edge of one of the descending pulses that follows said one of the ascending pulses, and has a second potential during a second time period beginning from the finishing edge of said one of the descending pulses and ending at a starting edge of another one of the ascending pulses that follows said one of the descending pulses.

The switch unit includes a switch for interconnecting the charge controller and the loop filter, and a capacitor connected to the charge controller and to the loop filter via the switch. The switch is controlled by the control signal from the control signal generator such that when the control signal has the first potential, the charge controller and the capacitor are disconnected from the loop filter and the current output of the charge controller is used to charge and discharge the capacitor so as to result in a floating voltage of the capacitor, and such that when the control signal has the second potential, the charge controller and the capacitor are connected to the loop filter to enable the loop filter to generate the control voltage corresponding to the floating voltage.

### BRIEF DESCRIPTION OF THE DRAWINGS

Other features and advantages of the present invention will become apparent in the following detailed description of the preferred embodiment with reference to the accompanying drawings, of which:

FIG. 1 is a schematic circuit block diagram of a conventional clock recovery circuit;

FIGS. 2A to 2E illustrate an input data signal (DATA), a clock signal (CLK), ascending pulses (UP), descending pulses (DN), and a control voltage (V_{ct}) generated in the conventional clock recovery circuit of FIG. 1;

FIG. 3 is a schematic circuit block diagram of a clock recovery circuit that incorporates the preferred embodiment of an apparatus for reducing clock jitter according to the present invention;

FIGS. 4A to 4G illustrate an input data signal (DATA), a clock signal (CLK), ascending pulses (UP), descending pulses (DN), a control signal (CTL), a control voltage (V_{coin}) and a charge/discharge voltage (Vₓ) generated in the clock recovery circuit of FIG. 3; and

FIG. 5 is an electrical circuit diagram showing a charge controller, a switch unit and a loop filter of the clock recovery circuit of FIG. 3.

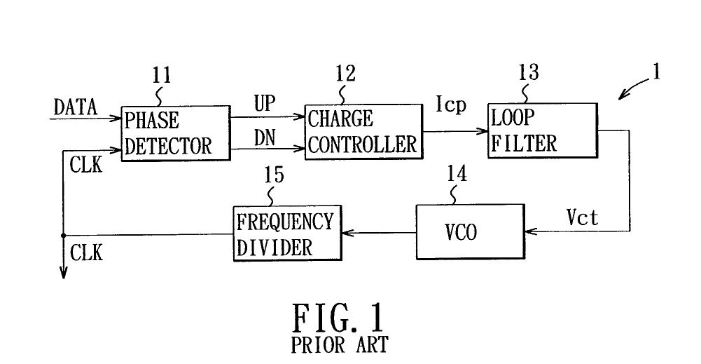

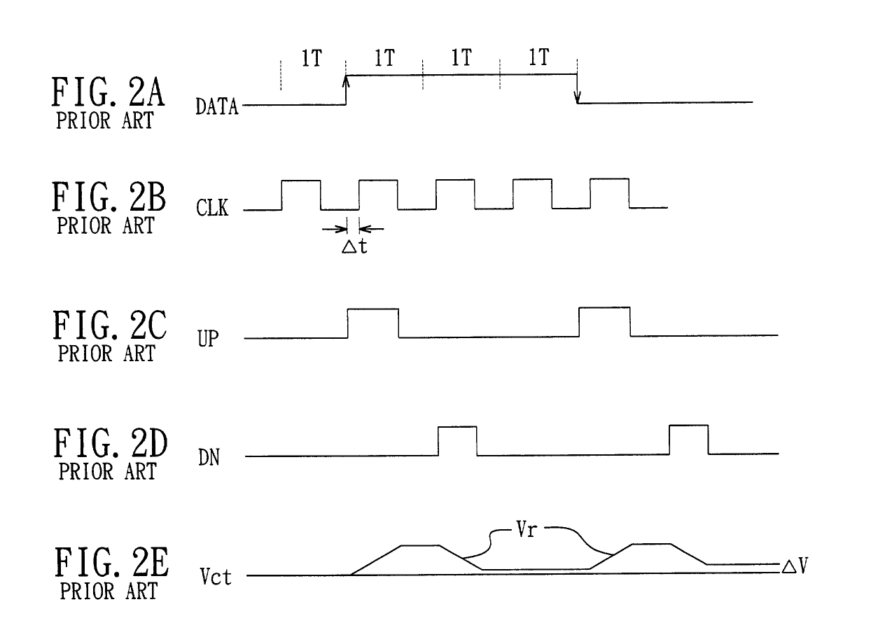

### DETAILED DESCRIPTION OF THE PREFERRED EMBODIMENT

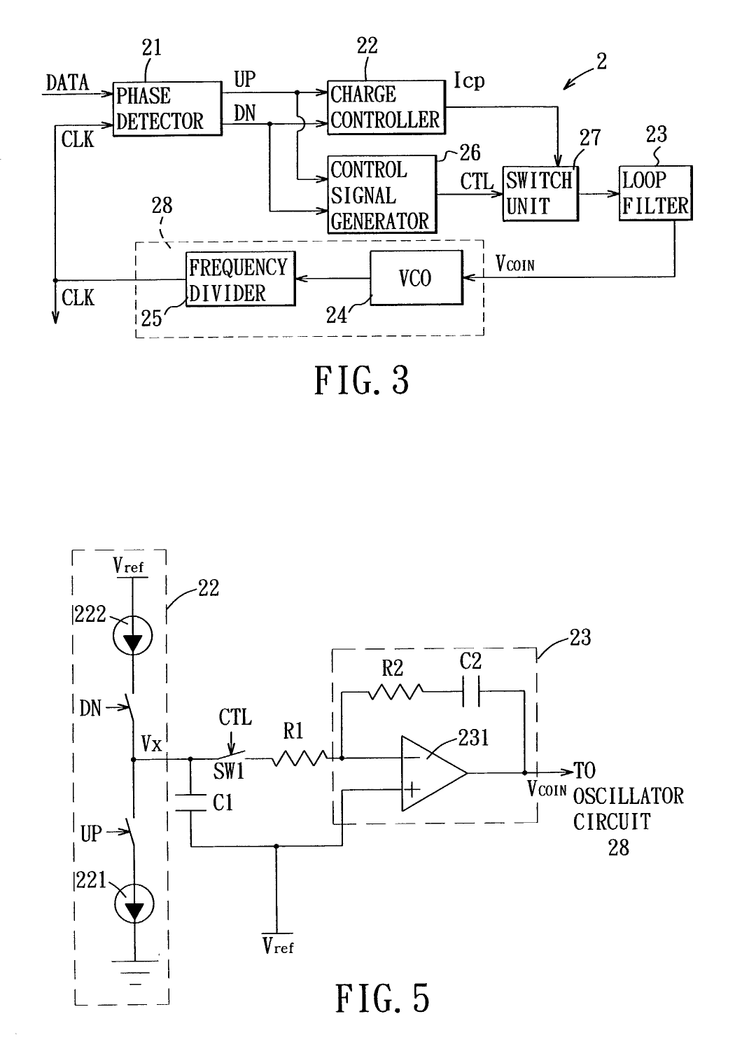

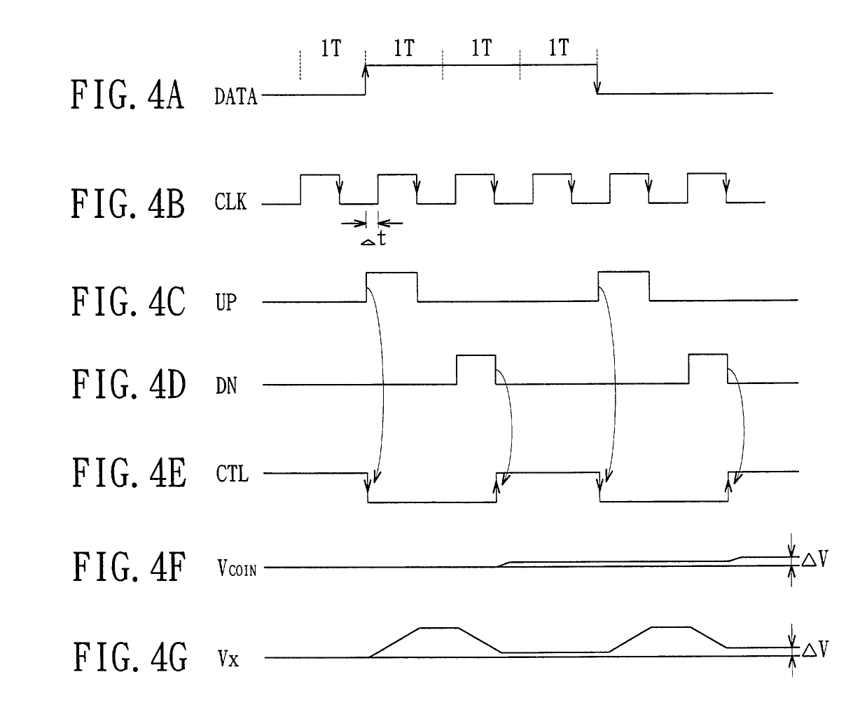

Referring to FIG. 3, the preferred embodiment of a method and apparatus for reducing clock jitter according to the present invention is shown to be implemented in a clock recovery circuit 2 that is used to generate a clock signal (CLK) for sampling an input data signal (DATA). The clock recovery circuit 2 includes a phase detector 21 for receiving the input data signal (DATA) (see FIG. 4A) and the clock signal (CLK) (see FIG. 4B), a charge controller 22 connected to the phase detector 21, a loop filter 23 to be connected to the charge controller 22, and an oscillator circuit 28 connected to the loop filter 23 and the phase detector 21. The oscillator circuit 28 includes a voltage-controlled oscillator (VCO) 24 connected to the loop filter 23, and a frequency divider 25 connected to the oscillator 24 and the phase detector 21. The frequency divider 25 processes a clock output from the oscillator 24 to result in the clock signal (CLK) that is provided to the phase detector 21. The phase detector 21 generates ascending pulses (UP) (see FIG. 4C) and descending pulses (DN) (see FIG. 4D) according to a phase difference (Δt) between the input data signal (DATA) and the clock signal (CLK). The charge controller 22 generates a current output (I_{cp}) according to the ascending and descending pulses (UP, DN) from the phase detector 21. The loop filter 23 generates a control voltage (V_{COIN}) (see FIG. 4F) for controlling the oscillator circuit 28 to synchronize the clock signal (CLK) with the input data signal (DATA).

Due to the characteristics of the phase detector 21, the starting edge of the ascending pulse (UP) is controlled by the starting or finishing edge of the input data signal (DATA), while the starting edge of the descending pulse (DN) is controlled by the starting edge of a clock pulse of the clock signal (CLK) that follows the ascending pulse (UP). The width of the descending pulse (DN) corresponds to that of the clock pulse of the clock signal (CLK), and there is no overlap between the ascending pulse (UP) and the descending pulse (DN).

In the conventional clock recovery circuit 1 described beforehand, the control voltage (V_{ct}) that is provided by the loop filter 13 to the oscillator 14 contains undesired ripples (Vᵣ) that drive the oscillator 14 to continuously change the phase of the clock signal (CLK), which results in phase jitter of the clock signal (CLK) and which can result in data sampling error.

In order to overcome the aforesaid drawback, the present invention provides an apparatus that includes a control signal generator 26 connected to the phase detector 21, and a switch unit 27 connected to the control signal generator 26.

The control signal generator 26 is preferably in the form of a logic circuit, and generates a control signal (CTL) (see FIG. 4E), which is in the form of a square wave, from the ascending and descending pulses (UP, DN) generated by the phase detector 21. During a first time period beginning from a starting edge of one of the ascending pulses (UP) and ending at a finishing edge of one of the descending pulses (DN) that follows said one of the ascending pulses (UP), the control signal (CTL) has a first potential, which is a low logic state in this embodiment. During a second time period beginning from the finishing edge of said one of the descending pulses (DN) and ending at a starting edge of another one of the ascending pulses (UP) that follows said one of the descending pulses (DN), the control signal (CTL) has a second potential, which is a high logic state in this embodiment. Therefore, the control signal (CTL) has a falling edge controlled by a rising edge of one of the ascending pulses (UP), and a rising edge controlled by a falling edge of one of the descending pulses (DN).

Referring further to FIG. 5, the switch unit 27 includes a control switch (SW1), a first capacitor (C1) and a first resistor (R1). The charge controller 22 includes a pair of current sources 221, 222 controlled by the ascending pulses (UP) and the descending pulses (DN), respectively. The loop filter 23 includes an operational amplifier 231, a second resistor (R2) and a second capacitor (C2). The second resistor (R2) has one end connected to an inverting input of the operational amplifier 231, and the other end connected to one end of the second capacitor (C2). The other end of the second capacitor (C2) is connected to an output of the operational amplifier 231. The first capacitor (C1) interconnects the charge controller 23 and a non-inverting input of the operational amplifier 231. The non-inverting input of the operational amplifier 231 is connected to a voltage source (V_{ref}). The charge controller 22 and the first capacitor (C1) are connected to the inverting input of the operational amplifier 231 via a series connection of the first resistor (R1) and the control switch (SW1).

As mentioned beforehand, the phase detector 21 generates the ascending and descending pulses (UP, DN) according to the phase difference (Δt) between the input data signal (DATA) and the clock signal (CLK). The ascending and descending pulses (UP, DN) are provided to the charge controller 22 to enable the latter to generate the current output (I_{cp}) in a manner similar to that of the conventional clock recovery circuit 1 described beforehand. However, in the present invention, the ascending and descending pulses (UP, DN) are further provided to the control signal generator 26. Therefore, during the first time period, the low logic state of the control signal (CTL) from the control signal generator 26 can be used to turn off the control switch (SW1) such that the charge controller 22 and the first capacitor (C1) are disconnected from the inverting input of the operational amplifier 231 of the loop filter 23. At this time, the current output (I_{cp}) of the charge controller 22 can be used to charge and discharge the first capacitor (C1). Particularly, the first capacitor (C1) is charged when the ascending pulse (UP) is present, and is discharged when the descending pulse (DN) is present. The change in the charge/discharge voltage (Vₓ) is shown in FIG. 4G. During the first time period, the first capacitor (C1) will have a floating voltage (V_{cp}) that corresponds to the phase difference (Δt). Thereafter, during the second time period, the high logic state of the control signal (CTL) can be used to turn on the control switch (SW1) such that the charge controller 22 and the first capacitor (C1) are connected to the inverting input of the operational amplifier 231 of the loop filter 23 via the first resistor (R1). At this time, even though the charge controller 22 is connected to the loop filter 23, because the ascending and descending pulses (UP, DN) have low potentials, the charge controller 22 will not generate the current output (I_{cp}) such that charging and discharging of the first capacitor (C1) through the charge controller 22 does not occur. Therefore, the floating voltage (V_{c1}) of the first capacitor (C1) can be used to charge the second capacitor (C2) through the first and second resistors (R1, R2), thereby enabling the loop filter 23 to generate the control voltage (V_{coin}) that is provided to the oscillator 24 for synchronizing the clock signal (CLK) with the input data signal (DATA).

In summary, this invention generates a control signal (CTL) according to the ascending and descending pulses (UP, DN) from the phase detector 21. The control signal (CTL) controls the connecting relationships among the first capacitor (C1), the charge controller 22 and the loop filter 23. During the first time period, the charge controller 22 and the first capacitor (C1) are disconnected from the loop filter 23 such that the current output (I_{cp}) of the charge controller 22 as a result of the ascending and descending pulses (UP, DN) from the phase detector 21 charge and discharge the first capacitor (C1), thus resulting in a floating voltage (V_{c1}) of the first capacitor (C1) that corresponds to the phase difference (Δt) between the input data signal (DATA) and the clock signal (CLK). During the second time period, the charge controller 23 and the first capacitor (C1) are connected to the loop filter 23 such that the loop filter 23 is able to generate the control voltage (V_{coin}) corresponding to the floating voltage (V_{c1}) for controlling operation of the oscillator 24. Because the current output (I_{cp}) of the charge controller 22 is used to charge and discharge the first capacitor (C1), and because the control voltage (V_{coin}) of the loop filter 23 is generated according to the floating voltage (V_{c1}) of the first capacitor (C1), ripples attributed to the non-overlapping ascending and descending pulses (UP, DN) are accordingly eliminated. Therefore, the frequency of the clock output of the oscillator 24 will only change in accordance with the detected phase difference (Δt) between the input data signal (DATA) and the clock signal (CLK), and the control voltage (V_{coin}) from the loop filter 23 will no longer contain ripples that can result in phase jitter of the clock signal (CLK). As such, accurate sampling of the input data signal (DATA) is possible after the clock signal (CLK) and the input data signal (DATA) are synchronized.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

I claim:

1. A method for reducing clock jitter in a clock recovery circuit, the clock recovery circuit including a phase detector for receiving an input data signal and a clock signal, a charge controller connected to the phase detector, a loop filter to be connected to the charge controller, and an oscillator circuit connected to the loop filter and the phase detector, the oscillator circuit including a voltage-controlled oscillator and providing the clock signal to the phase detector, the phase detector generating ascending and descending pulses according to phase difference between the input data signal and the clock signal, the charge controller generating a current output according to the ascending and descending pulses from the phase detector, the loop filter generating a control voltage for controlling the oscillator circuit to synchronize the clock signal with the input data signal, said method comprising the steps of:
generating a control signal from the ascending and descending pulses, the control signal having a first potential during a first time period beginning from a starting edge of one of the ascending pulses and ending at a finishing edge of one of the descending pulses that follows said one of the ascending pulses, and having a second potential during a second time period beginning from the finishing edge of said one of the descending pulses and ending at a starting edge of another one of the ascending pulses that follows said one of the descending pulses;
using the current output of the charge controller to charge and discharge a capacitor when the control signal has the first potential such that the capacitor has a floating voltage; and
connecting the capacitor to the loop filter to enable the loop filter to generate the control voltage corresponding to the floating voltage when the control signal has the second potential.

2. The method as claimed in claim 1, wherein the control signal is in the form of a square wave, the first potential being a low logic state, the second potential being a high logic state.

3. The method as claimed in claim 2, wherein the control signal has a falling edge controlled by a rising edge of one of the ascending pulses, and a rising edge controlled by a falling edge of one of the descending pulses.

4. An apparatus for reducing clock jitter in a clock recovery circuit, the clock recovery circuit including a phase detector for receiving an input data signal and a clock signal, a charge controller connected to the phase detector, a loop filter to be connected to the charge controller, and an oscillator circuit connected to the loop filter and the phase detector, the oscillator circuit including a voltage-controlled oscillator and providing the clock signal to the phase detector, the phase detector generating ascending and descending pulses according to phase difference between the input data signal and the clock signal, the charge controller generating a current output according to the ascending and descending pulses from the phase detector, the loop filter generating a control voltage for controlling the oscillator circuit to synchronize the clock signal with the input data signal, said apparatus comprising:
a control signal generator adapted to be connected to the phase detector and adapted to generate a control signal from the ascending and descending pulses, wherein the control signal has a first potential during a first time period beginning from a starting edge of one of the ascending pulses and ending at a finishing edge of one of the descending pulses that follows said one of the ascending pulses, and has a second potential during a second time period beginning from the finishing edge of said one of the descending pulses and ending at a starting edge of another one of the ascending pulses that follows said one of the descending pulses; and
a switch unit connected to said control signal generator and including a switch adapted to interconnect the charge controller and the loop filter, and a capacitor adapted to be connected to the charge controller and to the loop filter via said switch;
said switch being controlled by the control signal from said control signal generator such that when the control signal has the first potential, the charge controller and said capacitor are disconnected from the loop filter and the current output of the charge controller is used to charge and discharge said capacitor so as to result in a floating voltage of said capacitor, and such that when the control signal has the second potential, the charge controller and said capacitor are connected to the loop filter to enable the loop filter to generate the control voltage corresponding to the floating voltage.

5. The apparatus as claimed in claim 4, wherein the control signal is in the form of a square wave, the first potential being a low logic state, the second potential being a high logic state.

6. The apparatus as claimed in claim 5, wherein the control signal has a falling edge controlled by a rising edge of one of the ascending pulses, and a rising edge controlled by a falling edge of one of the descending pulses.

7. A clock recovery circuit comprising:
a phase detector for receiving an input data signal and a clock signal;
a charge controller connected to said phase detector;
a loop filter to be connected to said charge controller;
an oscillator circuit connected to said loop filter and said phase detector, said oscillator circuit including a voltage-controlled oscillator and providing the clock signal to said phase detector;
said phase detector generating ascending and descending pulses according to phase difference between the input data signal and the clock signal;
said charge controller generating a current output according to the ascending and descending pulses from said phase detector;
said loop filter generating a control voltage for controlling said oscillator circuit to synchronize the clock signal with the input data signal;
a control signal generator connected to said phase detector and generating a control signal from the ascending and descending pulses, wherein the control signal has a first potential during a first time period beginning from a starting edge of one of the ascending pulses and ending at a finishing edge of one of the descending pulses that follows said one of the ascending pulses, and has a second potential during a second time period beginning from the finishing edge of said one of the descending pulses and ending at a starting edge of another one of the ascending pulses that follows said one of the descending pulses; and
a switch unit connected to said control signal generator and including a switch for interconnecting said charge controller and said loop filter, and a first capacitor connected to said charge controller and to said loop filter via said switch;
said switch being controlled by the control signal from said control signal generator such that when the control signal has the first potential, said charge controller and said first capacitor are disconnected from said loop filter and the current output of said charge controller is used to charge and discharge said first capacitor so as to result in a floating voltage of said first capacitor, and such that when the control signal has the second potential, said charge controller and said first capacitor are connected to said loop filter to enable said loop filter to generate the control voltage corresponding to the floating voltage.

8. The clock recovery circuit as claimed in claim 7, wherein the control signal is in the form of a square wave, the first potential being a low logic state, the second potential being a high logic state.

9. The clock recovery circuit as claimed in claim 8, wherein the control signal has a falling edge controlled by a rising edge of one of the ascending pulses, and a rising edge controlled by a falling edge of one of the descending pulses.

10. The clock recovery circuit as claimed in claim 7, wherein said switch unit further includes a first resistor interconnecting said switch and said loop filter,
said loop filter including an operational amplifier having an inverting input connected to said first resistor, a non-inverting input adapted to be connected to a voltage source, and an output,
said loop filter further including a series connection of a second resistor and a second capacitor connected between said inverting input and said output of said operational amplifier,
said first capacitor being connected between said charge controller and said non-inverting input of said operational amplifier.
